(19) United States
(12) Patent Application Publication
(10) Pub. No.: US 2026/0005052 A1
(43) Pub. Date: Jan. 1, 2026

(54) SUBSTRATE PROCESSING APPARATUS

(71) Applicant: SCREEN HOLDINGS CO., LTD., Kyoto (JP)

(72) Inventors: Kenji AMAHISA, Kyoto-shi, Kyoto (JP); Shinichi TANIGUCHI, Kyoto-shi, Kyoto (JP); Akihiro IWASAKI, Kyoto-shi, Kyoto (JP)

(21) Appl. No.: 18/849,983

(22) PCT Filed: Mar. 16, 2023
(86) PCT No.: PCT/JP2023/010211

§ 371 Date: May 6, 2025

(30) Foreign Application Priority Data
Mar. 24, 2022 (JP) 2022-048786

(51) Int. Cl. H01L 21/677; B08B 3/04; H01L 21/67

(52) U.S. Cl. CPC H01L 21/67718; B08B 3/04; H01L 21/67727; H01L 21/67057

(57) ABSTRACT

In a substrate processing apparatus, a carrier that contains a plurality of substrates is transported by a plurality of transport devices on a predetermined transport path from a start point to an end point. In a processing section provided in part of the transport path, a predetermined process is executed on the plurality of substrates contained in the carrier by a liquid processing unit. In the transport path, a posture changer that changes the posture of the carrier between a vertical posture and a horizontal posture is provided. The posture changer changes the posture of the carrier such that the carrier keeps the vertical posture in the processing portion and the carrier is kept having the horizontal posture in the portion except for the processing section.

### TECHNICAL FIELD

The present invention relates to a substrate processing apparatus that processes a plurality of substrates using a processing tank.

### BACKGROUND ART

A substrate processing apparatus is used to execute various processes on a substrate such as a semiconductor substrate, a substrate for an FPD (Flat Panel Display) that is used for a liquid crystal display device, an organic EL (Electro Luminescence) display device or the like, a substrate for an optical disc, a substrate for a magnetic disc, a substrate for a magneto-optical disc, a substrate for a photomask, a ceramic substrate or a substrate for a solar cell.

As such a substrate processing apparatus, there is a batch-type substrate processing apparatus that executes a process such as etching by immersing a plurality of substrates in a processing liquid stored in a processing tank. For example, a batch-type substrate processing apparatus described in Patent Document 1 includes a FOUP holder, a substrate processing section or and a carry-in carry-out mechanism. The FOUP holder is configured to be capable of holding a FOUP (Front Opening Unified Pod). The FOUP is a container configured to be capable of holding and containing a plurality of substrates with the substrates having a horizontal posture such that the plurality of substrates are arranged at a predetermined pitch in an upward-and-downward direction.

In the substrate processing apparatus, a FOUP containing a plurality of unprocessed substrates is supplied to and held by the FOUP holder. In this state, the plurality of substrates are taken out from the FOUP by a hand included in the carry-in carry-out mechanism. The hand is configured to be capable of collectively holding a plurality of substrates. The plurality of substrates taken out by the hand are transferred to the substrate processing section via the plurality of transport mechanisms and a support mechanism.

The substrate processing section includes a plurality of processing tanks and a main transport mechanism. Each of the plurality of processing tanks stores a processing liquid for executing a predetermined process on a substrate. Each of the plurality of unprocessed substrates transferred to the substrate processing section is transported to a position above any of the plurality of processing tanks by the main transport mechanism. The main transport mechanism is also configured to be capable of collectively holding a plurality of substrates similarly to the above-mentioned hand.

The plurality of substrates that have been transported to the position above one of the plurality of processing tanks are immersed for a certain period of time in the processing liquid in the processing tank below the plurality of substrates and then pulled up. Thus, a predetermined process is executed on the plurality of substrates. The plurality of processed substrates are taken out from the substrate processing section, and are inserted into an empty FOUP held by the FOUP holder via the plurality of transport mechanisms and the support mechanism. The FOUP containing the plurality of processed substrates is carried out from the substrate processing apparatus.

[Patent Document 1] JP 2011-238945 A

### SUMMARY OF INVENTION

### Technical Problem

As described above, in the substrate processing apparatus described in Patent Document 1, the plurality of substrates are integrally received and transferred among the plurality of transport mechanisms. These plurality of transport mechanisms have a relatively complicated configuration for collectively holding the plurality of substrates. Such a complicated configuration complicates the maintenance work such as cleaning the plurality of transport mechanisms.

Further, in the above-mentioned substrate processing apparatus, after being taken out from the FOUP, the plurality of substrates are transported by the plurality of transport mechanisms while keeping a vertical posture in the period from the time immediately before being transferred to the substrate processing section to the time when being inserted into an empty FOUP. In this case, each of the plurality of transport mechanisms supports the lower end portion or its vicinity of each of the plurality of substrates having the vertical posture. Therefore, the weight of the substrate is likely to be exerted in a concentrated manner on a supported portion in the lower end portion or its vicinity of each of the above-mentioned substrates. When the substrate is transported over a long distance in this state, the supported portion of the substrate may be damaged.

An object of the present invention is to provide a substrate processing apparatus that can suppress complication of a configuration of a transport mechanism and can reduce the possibility of damage to a substrate.

### Solution to Problem

(1) A substrate processing apparatus according to one aspect of the present invention includes a carrier configured to contain a plurality of substrates, a transport mechanism that transports the carrier in one predetermined transport direction on a predetermined transport path, a processing unit that is provided on a predetermined processing portion of the transport path, and executes a predetermined process on the plurality of substrates contained in the carrier, the plurality of substrates being contained in the carrier, and a posture changer that changes a posture of the carrier between a first posture with which the plurality of substrates are containable while having a vertical posture and a second posture with which the plurality of substrates are containable while having a horizontal posture, wherein the posture changer is provided on the transport path such that the carrier keeps the first posture in the processing portion of the transport path and the carrier keeps the second posture in at least part of a non-processing portion excluding the processing portion of the transport path with the plurality of substrates contained in the carrier.

In the substrate processing apparatus, the carrier is transported in one transport direction on the transport path by the transport mechanism. The carrier is configured to be capable of containing the plurality of substrates. In this case, the transport mechanism can integrally handle the plurality of substrates by transporting the carrier containing the plurality of substrates. Therefore, the transport mechanism does not require a complicated configuration for integrally and directly holding the plurality of substrates.

Further, in the above-mentioned substrate processing apparatus, the posture of the carrier is changed between the first posture and the second posture by the posture changer provided on the transfer path. Thus, the carrier keeps the first posture in the processing portion of the transport path. In this case, in the processing portion, because the plurality of substrates contained in the carrier have the vertical posture, it is possible to execute a collective process on the plurality of substrates W, such as a process of immersing the plurality of substrates in a processing liquid.

On the other hand, in at least part of the non-processing portion of the transport path, the carrier keeps the second posture. When the posture of the carrier is the second posture, the plurality of substrates contained in the carrier keeps the horizontal posture. In regard to each of the plurality of substrates, the size of the substrate having the horizontal posture in plan view is larger than the size of the substrate having the vertical posture in plan view. Therefore, the substrate having the horizontal posture can support a large portion of the substrate as compared to the substrate having the vertical posture. This reduces the possibility that each substrate is damaged due to the concentration of the weight of the substrate on one portion of the substrate when the substrates are transported.

As a result, it is possible to suppress complication of the configuration of the transport mechanism and reduce the possibility of damage to the substrate during the transport of the substrate.
(2) The processing unit may include a processing tank that stores a processing liquid corresponding to the predetermined process, and a lifter configured to immerse the carrier transported by the transport mechanism in a processing liquid of the processing tank and pull up the carried immersed in the processing liquid from the processing liquid, and because the plurality of substrates are immersed in the processing liquid while being contained in the carrier and having the first posture, the carrier may be configured to immerse the plurality of substrates contained in the carrier in the processing liquid.

In this case, in the processing unit, the carrier keeps the first posture, so that it is possible to execute an appropriate process on the plurality of substrates contained in the carrier by immersing the carrier in the processing liquid in the processing tank.
(3) The substrate processing apparatus may further include a substrate carry-in carry-out portion that is configured to carry a plurality of unprocessed substrates and insert the plurality of carried substrates into one carrier, and take out a plurality of substrates from another carrier containing the plurality of processed substrates and carry out the plurality of taken substrates, wherein a start point and an end point of the transport path may be set adjacent to the substrate carry-in carry-out portion, the processing portion of the transport path may be defined in a continuous range including the end point of the transport path, and in the transport path, the posture changer may be located at a position farther downstream than at least part of the non-processing portion and farther upstream than the processing portion.

In this case, the posture of the carrier that is transported while having the second posture in at least part of the non-processing portion is changed to the first posture by the posture changer, and the carrier is transported while having the first posture in the processing portion. Therefore, the substrates immersed in the processing liquid together with the carrier in the processing portion are not transported in the non-processing portion. Therefore, because the plurality of processed substrates are not transported while having the horizontal posture, it reduces adhesion of falling particles and the like to each substrate. Further, because the substrate after the process using the processing bath is not transported while having the horizontal posture, the processing liquid is prevented from remaining on the upper surface of each of the plurality of substrates during the transport.
(4) At least part of the non-processing portion of the transport path may be located in one horizontal plane, the transport mechanism may include a horizontal transport device provided in at least part of the non-processing portion of the transport path, and the horizontal transport device may include a guide member extending horizontally along the transport path, and a movable stage on which the carrier is placeable and which is movable along the transport path on the guide member.

In this case, in at least part of the non-processing portion of the transport path, the movable stage moves on the guide member with the carrier placed on the movable stage. Thus, the carrier is transported while having the horizontal posture. Thus, with the above-mentioned horizontal transport device, in at least part of the non-processing portion of the transport path, the carrier can be transported without moving in the vertical direction. Therefore, in at least part of the non-processing portion of the transport path, the size in the vertical direction of the space required for the transport can be reduced.
(5) The carrier may be formed such that a dimension in a vertical direction of the carrier having the second posture is smaller than a dimension in the vertical direction of the carrier having the first posture.

In this case, in the portion of the transport path where the carrier keeps the second posture, the size in the vertical direction of the space required for the transport can be reduced as compared to the portion of the transport path where the carrier keeps the first posture.
(6) The carrier may have a first supporter that supports a first supported portion of each of the plurality of substrates when the carrier has the first posture, and a second supporter that supports a second supported portion of each of the plurality of substrates when the carrier has the second posture, and a size of the second supported portion of the substrate obtained when each of the plurality of substrates having a horizontal posture is seen in plan view may be larger than a size of the first supported portion of the substrate obtained when each of the plurality of substrates having a vertical posture is seen in plan view.

In this case, with the plurality of substrates held by the carrier having the second posture, each of the plurality of substrates is supported by the first supported portion. Further, with the plurality of substrates held by the carrier having the first posture, each of the plurality of substrates is supported by the second supported portion. In this case, because the second supported portion obtained when each substrate is seen in plan view is larger than the first supported portion obtained when each substrate is seen in plan view, a load applied to the second supported portion of each substrate contained in the carrier is reduced with the carrier having the second posture.

### Advantageous Effects of Invention

With the present invention, it is possible to suppress complication of the configuration of a transport mechanism and reduce the possibility of damage to a substrate during the transport of the substrate.

### BRIEF DESCRIPTION OF THE DRAWINGS

FIG. 1 is a schematic plan view showing the basic configuration of a substrate processing apparatus according to one embodiment of the present invention.

FIG. 2 is a schematic cross sectional view of the substrate processing apparatus taken along the line A-A of FIG. 1.

FIG. 3 is a plan view of a carrier used in the substrate processing apparatus of FIG. 1.

FIG. 4 is a side view of one side of a carrier of FIG. 3.

FIG. 5 is a cross-sectional view of the carrier taken along the line B-B of FIG. 4.

FIG. 6 is a plan view showing a supported portion of a substrate which changes in accordance with a posture of the carrier.

FIG. 7 is a diagram for explaining a transport path for a plurality of substrates and the carrier in the substrate processing apparatus of FIG. 1.

FIG. 8 is a diagram for explaining the transport path for the plurality of substrates and the carrier in the substrate processing apparatus of FIG. 1.

FIG. 9 is a diagram for explaining the transport path for the plurality of substrates and the carrier in the substrate processing apparatus of FIG. 1.

### DESCRIPTION OF EMBODIMENTS

A substrate processing apparatus according to one embodiment of the present invention will be described below with reference to the drawings. In the following description, a substrate refers to a substrate for an FPD (Flat Panel Display) that is used for a liquid crystal display device, an organic EL (Electro Luminescence) display device or the like, a semiconductor substrate, a substrate for an optical disc, a substrate for a magnetic disc, a substrate for a magneto-optical disc, a substrate for a photomask, a ceramic substrate, a substrate for a solar cell or the like. Further, a substrate, described below, has a rectangular shape in plan view.

### <1> Configuration of Substrate Processing Apparatus

### (1) Overall Configuration and Definition of Directions

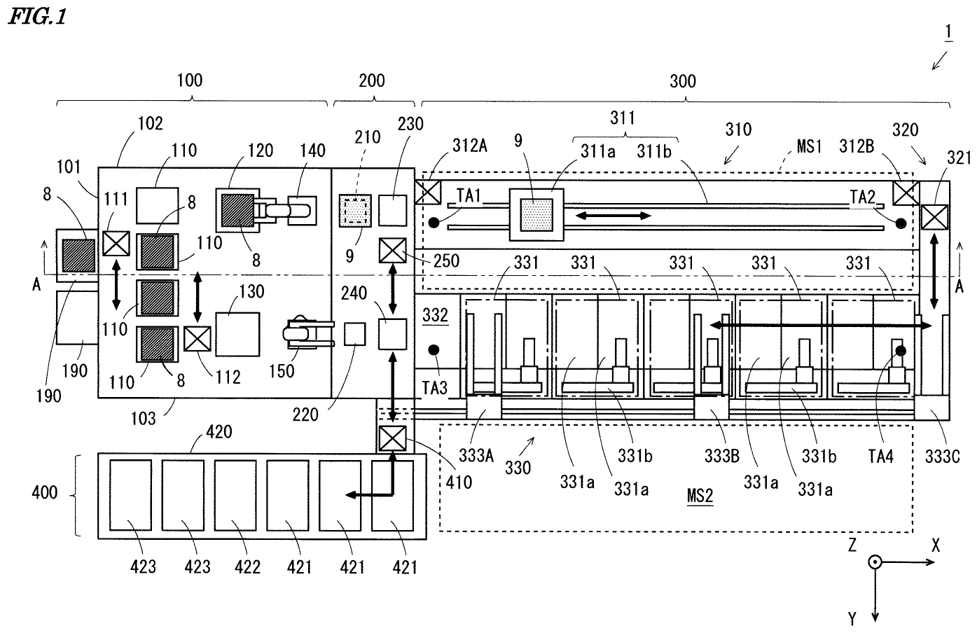

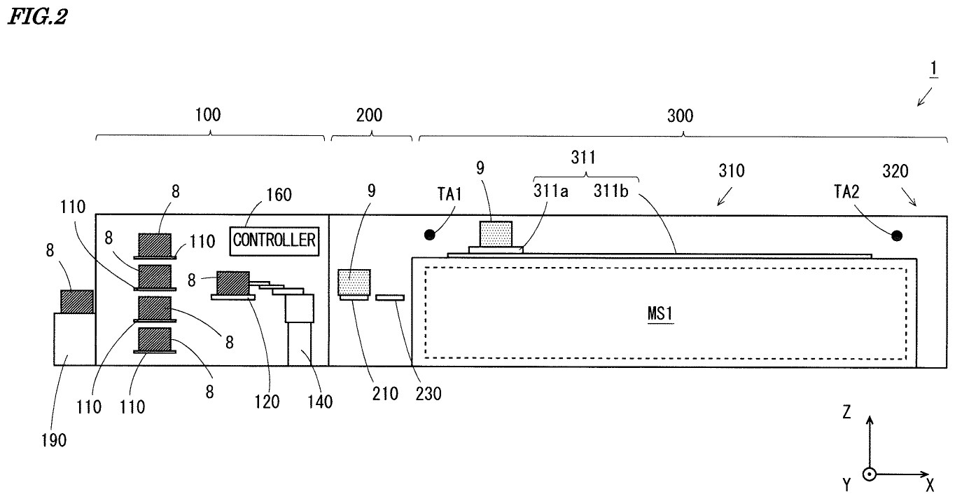

FIG. 1 is a schematic plan view showing the basic configuration of the substrate processing apparatus according to the one embodiment of the present invention. FIG. 2 is a schematic cross sectional view of the substrate processing apparatus 1 taken along the line A-A of FIG. 1. As shown in FIGS. 1 and 2, the substrate processing apparatus 1 mainly includes a substrate carry-in carry-out block 100, a relay block 200, a processing block 300 and a cleaning block 400.

Here, FIG. 1 and the subsequent drawings are accompanied by the arrows that indicate X, Y and Z directions orthogonal to one another for the clarity of the positional relationship among respective constituent elements of the substrate processing apparatus 1. The X and Y directions are orthogonal to each other within a horizontal plane, and the Z direction corresponds to a vertical direction. Further, in each direction, the direction in which the arrow is directed is a + direction, and the direction opposite to the + direction is a − direction. In the following description, when simply referred to as an X direction, the X direction includes a +X direction and a −X direction. Further, when simply referred to as a Y direction, the Y direction includes a +Y direction and a −Y direction. Further, when simply referred to as a Z direction, the Z direction includes a +Z direction and a −Z direction.

### (2) Substrate Carry-in Carry-out Block 100

The substrate carry-in carry-out block 100 includes a plurality of FOUP shelves 110, FOUP transport devices 111, 112, openers 120, 130, substrate receiving-transferring robots 140, 150, two FOUP platforms 190 and a controller 160 (FIG. 2). Further, the substrate carry-in carry-out block 100 has an end-surface portion 101, one side-surface portion 102 and another side-surface portion 103 which form part of the outer wall of the substrate processing apparatus 1. The end-surface portion 101 is located at one end of the substrate processing apparatus 1 directed in the −X direction and is orthogonal to the X direction. The one side-surface portion 102 and the other side-surface portion 103 extend in parallel with the +X direction from both end portions of the end-surface portion 101 in plan view so as to face each other in the Y direction.

The two FOUP platforms 190 are provided so as to project from the end-surface portion 101 in the −X direction. Each FOUP platform 190 is configured such that a FOUP (Front Opening Unified Pod) 8 that contains a plurality of substrates in a stack can be placed on the FOUP platform 190. In the end-surface portion 101, a passage opening (not shown) for allowing the FOUP 8 to pass therethrough in the X direction is formed in the portion corresponding to each FOUP platform 190.

In the FOUP 8, an opening through which substrates are taken out from the inner space of the FOUP 8 and through which the substrates are inserted into the inner space of the FOUP 8 is formed. Further, the FOUP 8 includes a lid for opening and closing the opening. The opening of the FOUP 8 is closed when the FOUP 8 is transported and when the FOUP 8 is waiting, and is opened when the substrate is taken out from the FOUP 8 and when the substrate is inserted into the FOUP 8. In FIGS. 1 and 2, in order to clearly distinguish the FOUP 8 from a carrier 9, described below, the hatching is applied to the FOUP 8, and the dotted pattern is applied to the carrier 9. In the example of FIG. 1, the FOUP 8 is placed on one FOUP platform 190 of the two FOUP platforms 190 arranged in the Y direction, and the FOUP 8 is not placed on the other FOUP platform 190.

The plurality of FOUP shelves 110 are provided so as to be spaced apart from one another at positions spaced apart from the end-surface portion 101 by a predetermined distance in the +X direction. In the present example, sixteen FOUP shelves 110 are fixed by fixing members (not shown) so as to be arranged in four rows and four columns in a plane parallel to the Z direction and the Y direction. Each FOUP shelve 110 is configured such that the FOUP 8 can be placed on the FOUP shelve 110. In the example of FIG. 1, among the four FOUP shelves 110 located at the top level, the FOUP 8 is placed on each of three FOUP shelves 110, and the FOUP 8 is not placed on the remaining one FOUP shelf 110. The number of FOUPs 8 and the arrangement of the FOUP shelves 110 may be suitably changed according to the apparatus design specifications.

The two openers 120, 130 are provided so as to be spaced apart from one another at positions spaced apart from the plurality of FOUP shelves 110 by a predetermined distance in the +X direction. In the present example, the two openers 120, 130 are fixed by fixing members (not shown) so as to be arranged in the Y direction. One opener 120 is located in the vicinity of the one side-surface portion 102, and the other opener 130 is located in the vicinity of the other side-surface portion 103. Each of the openers 120, 130 is configured such that the FOUP 8 can be placed on each of the openers 120, 130, and each of the openers 120, 130 is configured to be capable of opening and closing the lid of the FOUP 8. In the example of FIG. 1, the FOUP 8 is placed on the one opener 120, and the FOUP 8 is not placed on the other opener 130.

The substrate receiving-transferring robot 140 is provided to be adjacent to the opener 120 and located in the +X direction of the opener 120. The substrate receiving-transferring robot 140 is configured to be rotatable about an axis extending in the Z direction and movable (liftable and lowerable) in the Z direction. A hand for transferring and receiving one or a plurality of substrates is provided in the substrate receiving-transferring robot 140. The hand is supported by a multi-joint arm and can move forwardly and backwardly in a horizontal direction. The substrate receiving-transferring robot 140 is used to take out an unprocessed substrate from the FOUP 8 with the FOUP 8 containing the substrate and being located on the opener 120, and insert the taken substrate W into the below-mentioned carrier 9 arranged in the relay block 200.

The substrate receiving-transferring robot 150 is provided to be adjacent to the opener 130 and located in the +X direction of the opener 130. The substrate receiving-transferring robot 150 has the same configuration as that of the substrate receiving-transferring robot 140. The substrate receiving-transferring robot 150 is used to take out substrates from the below-mentioned carrier 9 arranged in the relay block 200 with the empty FOUP 8 placed on the opener 130, and insert the taken substrates into the FOUP 8 placed on the opener 130.

The FOUP transport device 111 is located between the end-surface portion 101 and the plurality of FOUP shelves 110 in the X direction. The FOUP transport device 111 has a holder (not shown) configured to be capable of holding the FOUP 8, and is configured to be capable of moving the holder in the Y direction and the Z direction. Thus, the FOUP transport device 111 transports the FOUP 8 between one of the two FOUP platforms 190 and one of the FOUP shelves 110.

The FOUP transport device 112 is located between the plurality of FOUP shelves 110 and the two openers 120, 130 in the X direction. The FOUP transport device 112 has the same configuration as that of the FOUP transport device 111. The FOUP transport device 112 transports the FOUP 8 between one of the plurality of FOUP shelves 110 and one of the two openers 120, 130.

The controller 160 (FIG. 2) is made of a computer or the like including a CPU (Central Processing Unit), a RAM (Random Access Memory) and a ROM (Read Only Memory), and controls each constituent element in the substrate processing apparatus 1.

### (3) Relay Block 200

The relay block 200 mainly includes two carrier supporters 210, 220, a first waiting portion 230, a second waiting portion 240 and a waiting transport device 250. The carrier supporter 210 is provided to be adjacent to the substrate receiving-transferring robot 140 in the substrate carry-in carry-out block 100 and located in the +X direction of the substrate carrying-transferring robot 140. Further, the carrier supporter 210 is configured to be capable of supporting the carrier 9 containing a plurality of substrates in a stack. Details of the carrier 9 will be described below. Further, the carrier supporter 210 is configured to be capable of supporting the carrier 9 and be capable of changing the posture of the supported carrier 9. Details of the configuration of the carrier supporter 210 for changing the posture of the carrier 9 will be described below. In the example of FIG. 1, the carrier 9 is supported on the carrier supporter 210.

The carrier supporter 220 is provided to be adjacent to the substrate receiving-transferring robot 150 in the substrate carry-in carry-out block 100 and located in the +X direction of the substrate receiving-transferring robot 150. Further, the carrier supporter 220 has the same configuration as that of the carrier supporter 210. In the example of FIG. 1, the carrier 9 is not supported on the carrier supporter 220.

The first waiting portion 230 is provided to be adjacent to the carrier supporter 210 and located in the +X direction of the carrier supporter 210. Further, the first waiting portion 230 is configured to be capable of supporting the carrier 9. Further, the first waiting portion 230 is configured to be capable of transferring the carrier 9 supported by the first waiting portion 230 to the carrier supporter 210 and receiving the carrier 9 supported by the carrier supporter 210 from the carrier supporter 210.

The first waiting portion 240 is provided to be adjacent to the carrier supporter 220 and located in the +X direction of the carrier supporter 220. Further, the second waiting portion 240 is configured to be capable of supporting the carrier 9. Further, the second waiting portion 240 is configured to be capable of transferring the carrier 9 supported by the second waiting portion 240 to the carrier supporter 220 and receiving the carrier 9 supported by the carrier supporter 220 from the carrier supporter 220.

The waiting transport device 250 is provided between the first waiting portion 230 and the second waiting portion 240. The waiting transport device 250 is configured to be capable of holding the carrier 9 and movable in the Y direction between the first waiting portion 230 and the second waiting portion 240. The waiting transport device 250 transports the carrier 9 supported by the second waiting portion 240, for example, to the first waiting portion 230.

### (4) Processing Block 300

The processing block 300 includes a first transport section 310, a second transport section 320 and a processing section 330. The first transport section 310 and the processing section 330 are arranged in this order in the +Y direction and provided so as to extend in parallel with each other in the +X direction from the relay block 200. The second transport section 320 is formed to extend in the Y direction and connects an end portion of the first transport section 310 being directed in the +X direction and an end portion of the processing section 330 being directed in the +X direction.

In the following description, out of both end portions of the first transport section 310 extending in the X direction, one end portion directed in the −X direction is suitably referred to as a first end portion TA1, and another end portion directed in the +X direction is suitably referred to as a second end portion TA2. Further, out of both end portions of the processing section 330 extending in the X direction, one end portion directed in the −X direction is suitably referred to as a third end portion TA3, and another end portion directed in the +X direction is suitably referred to as a fourth end portion TA4.

The first transport section 310 includes a main transport device 311 and two sub-transport devices 312A, 312B. The main transport device 311 includes a movable stage 311a and a guide rail 311b. The guide rail 311b is provided so as to extend from the first end portion TA1 to the second end portion TA2 of the first transport section 310. The movable stage 311a is configured to be movable in the X direction on the guide rail 311b, and the movable stage 311a is configured such that the carrier 9 can be placed on the movable stage 311a. The main transport device 311 further includes a driving mechanism (not shown) that moves the movable stage 311a in the X direction on the guide rail 311b. Thus, in a case in which the carrier 9 is placed on the movable stage 311a in the first end portion TA1 close to the relay block 200, the main transport device 311 transports the placed carrier 9 in the +X direction to the second end portion TA2 close to the second transport section 320.

The sub-transport device 312A and the sub-transport device 312B are respectively provided in the first end portion TA1 and the second end portion TA2 of the first transport section 310 in the X direction. In a case in which the carrier 9 containing unprocessed substrates is supported by the carrier supporter 210, the sub-transport device 312A places the carriers 9 on the movable stage 311a of the main transport device 311 arranged in the first end portion TA1. Further, the sub-transport device 312A transports the empty carrier 9 from the first waiting portion 230 to the carrier supporter 210. On the other hand, in a case in which the movable stage 311a on which the carrier 9 is placed is moved to the second end portion TA2, the sub-transport device 312B transfers the carrier 9 to a transport device 321, described below, in the second transport section 320.

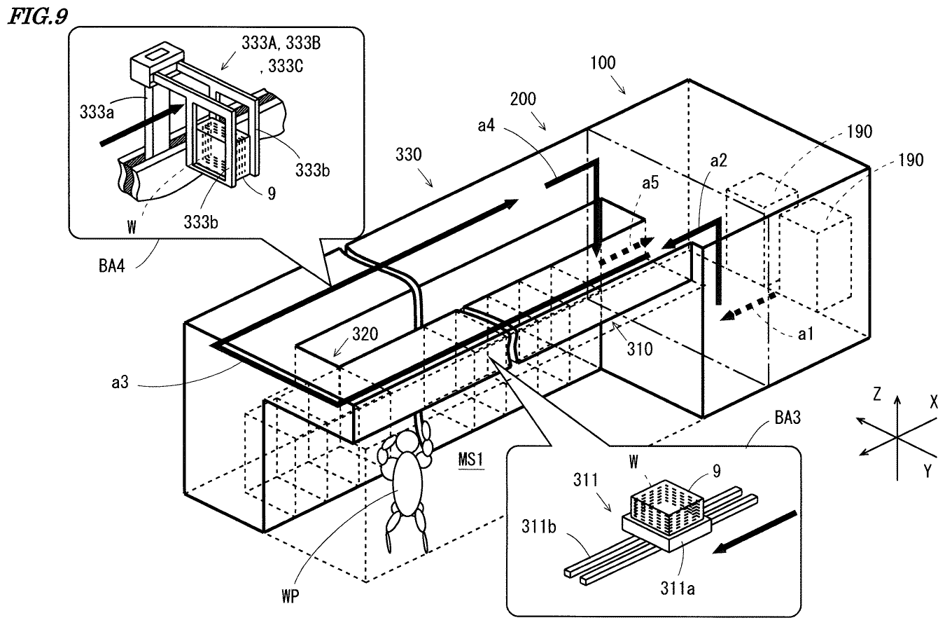

Here, as shown in FIG. 2, the first transport section 310 is provided at a position spaced apart from the installation surface of the substrate processing apparatus 1 in the +Z direction (upward direction). Thus, the space located in the −Z direction (downward direction) of the first transport section 310 can be utilized as a maintenance space MS1 for maintaining the below-mentioned processing section 330. Therefore, in the substrate processing apparatus 1 according to the present embodiment, as shown in FIG. 1, the first transport section 310 overlaps with the maintenance space MS1 of the processing section 330 in plan view. In FIG. 9, described below, a worker WP who performs a maintenance work on the processing section 330 below the first transport section 310 in the maintenance space MS1 is shown.

The second transport section 320 includes the transport device 321. The transport device 321 is configured to be capable of supporting the carrier 9 and changing the posture of the supported carrier 9. Details of the configuration of the transport device 321 for changing the posture of the carrier 9 will be described below. Further, the transport device 321 is configured to be movable in the Y direction. Thus, the second transport section 320 can receive the carrier 9 from the sub-transport device 312B in the vicinity of the second end portion TA2 of the first transport section 310. Further, the second transport section 320 can change the posture of the carrier 9 received from the sub-transport device 312B and move the carrier 9 to a position in the vicinity of the fourth end portion TA4 of the processing section 330.

The processing section 330 includes a plurality (five in the present example) of liquid processing units 331, a drying unit 332 and a plurality (three in the present example) of main transport devices 333A, 333B, 333C. The plurality of liquid processing units 331 and the drying unit 332 are arranged in the X direction such that the drying unit 332 is located in the third end portion TA3.

The plurality of main transport devices 333A, 333B, 333C are provided to be arranged in this order on one straight line extending in the +X direction from the third end portion TA3 toward the fourth end portion TA4. Each of the main transport devices 333A, 333B, 333C is configured to be capable of holding the carrier 9 and is configured to be capable of transporting the held carrier 9 among the plurality of liquid processing units 331 and the drying units 332. The main transport device 333C located farthest from the relay block 200 receives the carrier 9 in a case in which the carrier 9 is transported to a position in the vicinity of the processing section 330 in the second transport section 320. Further, the main transport device 333C transports the received carrier 9 to one of the plurality of liquid processing units 331.

Each of the plurality of liquid processing units 331 includes one or a plurality of processing tanks 331a and a lifter 331b. Each liquid processing unit 331 of the present example includes two processing tanks 331a. Each processing tank 331a is configured such that the carrier 9 can be inserted into and removed from the processing tank 331a from a position above the processing tank 331a. Further, the processing tank 331a stores a processing liquid (chemical liquid or rinse liquid) for cleaning the plurality of substrates contained in the carrier 9.

The lifter 331b of each liquid processing unit 331 is configured to be capable of holding the carrier 9. Further, the lifter 331b is configured to be capable of receiving the carrier 9 from one of the plurality of main transport devices 333A, 333B, 333C and transferring the carrier 9 to one of the plurality of main transport devices 333A, 333B, 333C. Further, the lifter 331b is configured to be capable of immersing the carrier 9 in the processing liquid and pulling up the carrier 9 from the processing liquid, in regard to each of the two processing tanks 331a of the liquid processing unit 331. Thus, the carrier 9 containing unprocessed substrates is transferred to the processing section 330, so that the plurality of substrates contained in the carrier 9 are immersed in one or a plurality of processing liquids for a predetermined period of time, and a common process is executed on the plurality of substrates.

The drying unit 332 executes a drying process on the carrier 9 transported by the main transport device 333A located at a position closest from the relay block 200. Due to this drying process, the plurality of substrates contained in the carrier 9 are dried. The carrier 9 after the drying process is transferred to the second waiting portion 240 of the relay block 200 by the main transport device 333A located at a position closest from the relay block 200.

Here, in the plurality of processing tanks 331a of the plurality of liquid processing units 331, a plurality of processing liquids respectively corresponding to a plurality of processes to be executed on substrates are stored so as to be arranged in the −X direction in the order of processes to be executed on the substrates. The controller 160 of FIG. 2 allows each of the main transport devices 333A, 333B, 333C to move in the −X direction while each of the main transport devices 333A, 333B, 333C holds the carrier 9, and restricts each of the main transport devices 333A, 333B, 333C from moving in the +X direction while each of the main transport devices 333A, 333B, 333C holds the carrier 9. In this case, when the plurality of carriers 9 are transported by the plurality of main transport devices 333A, 333B, 333C, interference caused by the movement of one carrier 9 and another carrier 9 in opposite directions is suppressed. Further, because the carrier 9 does not move back and forth in the X direction in the processing section 330, the length of the transport path for the carrier 9 in the processing section 330 does not exceed the length of the processing section 330 in the X direction.

As indicated by the dotted lines in FIG. 1, in the processing block 300 and the area in the vicinity of the processing block 300, in addition to the above-mentioned maintenance space MS1, another maintenance space MS2 is formed in the +Y direction of the processing section 330. In this manner, the two maintenance spaces MS1, MS2 are formed with the processing section 330 provided therebetween in the Y direction, so that a maintenance space having a sufficient size for the processing section 330 is ensured.

### (5) Cleaning Block 400

The cleaning block 400 includes a cleaning transport device 410 and a carrier cleaning unit 420. The carrier cleaning unit 420 is provided to extend in the X direction at a position sidewardly (in +Y direction) of the substrate carry-in carry-out block 100 and the relay block 200. Further, the carrier cleaning unit 420 includes a plurality of carrier cleaning tanks 421, a carrier dryer 422 and a plurality of carrier waiting portions 423 which are provided so as to be arranged in the X direction.

Each of the plurality of carrier cleaning tanks 421, the carrier dryer 422 and the plurality of carrier waiting portions 423 is configured such that the carrier 9 can be inserted into and taken out from the carrier 9 from a position above the tank, the drier or the waiting portion. Further, each of the plurality of carrier cleaning tanks 421 stores a processing liquid (a chemical liquid or a rinse liquid) for cleaning the carrier 9. The carrier dryer 422 executes a drying process on the inserted carrier 9.

The cleaning transport device 410 is configured to be capable of transporting the empty carrier 9 among the second waiting portion 240 in the relay block 200, the plurality of carrier cleaning tanks 421, the carrier drier 422 and the plurality of carrier waiting portions 423. In the cleaning block 400, the empty carrier 9 is transported among the plurality of carrier cleaning tanks 421 and immersed in the processing liquid stored in one of the carrier cleaning tanks 421. Thus, the empty carrier 9 after being used for the plurality of process for substrates in the processing block 300 is cleaned.

The cleaned carrier 9 is transported to the carrier drier 422 and subjected to a drying process. The dried carrier 9 is transported to the carrier waiting portion 423 to be held. Thereafter, the carrier 9 is taken out from the carrier waiting portion 423 by the cleaning transport device 410 in accordance with a point in time at which the plurality of substrates are accepted in the relay block 200, and transported to the second waiting portion 240 in the relay block 200.

### <2> Configuration of Carrier 9 and Posture of Carrier 9

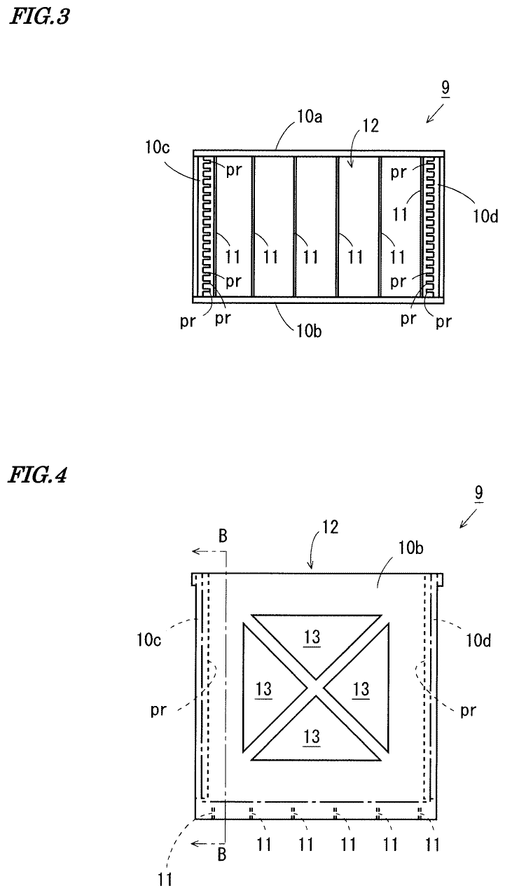

FIG. 3 is a plan view of the carrier 9 used in the substrate processing apparatus 1 of FIG. 1, FIG. 4 is a side view the carrier 9 of FIG. 3 as viewed in one direction, and FIG. 5 is a cross-sectional view of the carrier 9 taken along the line B-B of FIG. 4. As shown in FIGS. 3 to 5, the carrier 9 include four frame members 10a, 10b, 10c, 10d.

Each of the frame members 10a, 10b is formed of a substantially square plate-shaped member and has an outer shape larger than the substrate to be processed. Four openings 13 are formed in the center portion of each of the frame members 10a, 10b. Each of the frame members 10c, 10d is formed of a substantially oblong plate-shaped member. The length of the long edges of the frame members 10c, 10d is substantially equal to the length of one edge of the frame members 10a, 10b.

The frame members 10a, 10b are arranged so as to be spaced apart from each other while being opposite to each other. The frame member 10c is provided so as to connect one lateral edge of the frame member 10a and one lateral edge of the frame member 10b to each other. The frame member 10d is provided so as to connect the other lateral edge of the frame member 10a and the other lateral edge of the frame member 10b to each other. In this state, the frame members 10c, 10d are also arranged to be opposite to each other. Thus, the carrier 9 has a rectangular cylindrical shape.

A rectangular opening formed at one end of the carrier 9 having the rectangular cylindrical shape functions as a substrate inlet-outlet port 12 for inserting the substrate into the carrier 9 and taking out the substrate from the carrier 9. At the other end of the carrier 9, a plurality (six in the present example) of support pieces 11 are provided so as to connect the frame member 10a and the frame member 10b to each other, and to be arranged in a distributed manner between the frame member 10c and the frame member 10d.

Each support piece 11 is formed of an elongated plate-shaped member and is provided in parallel with the frame members 10c, 10d. Further, in each support piece 11, a plurality of grooves (not shown) into which portions of the outer edges of the plurality of substrates contained in the carrier 9 can be inserted are formed at a predetermined reference pitch. The number of grooves formed in each support piece 11 is equal to the number of substrates to be contained in the carrier 9.

A plurality of projections pr are formed on each of the two surfaces of the frame members 10c, 10d opposite to each other. The plurality of projections pr are formed to continuously extend in the direction in which the long edges of the frame members 10c, 10d extend and to be arranged at the above-mentioned reference pitch in the direction in which the short edges extend. Thus, a groove into which the outer edge of the substrate can be inserted is formed between each two adjacent projections pr.

As described above, in the substrate processing apparatus 1 of FIG. 1, the posture of the carrier 9 is suitably changed. Here, in regard to the carrier 9 having the above-mentioned configuration, the posture with which the plurality of support pieces 11 are located at the lower end and the frame members 10a, 10b are kept in parallel with the vertical direction is referred to as a vertical posture. On the other hand, the posture with which the frame members 10a, 10b are kept orthogonal to the vertical direction is referred to as a horizontal posture.

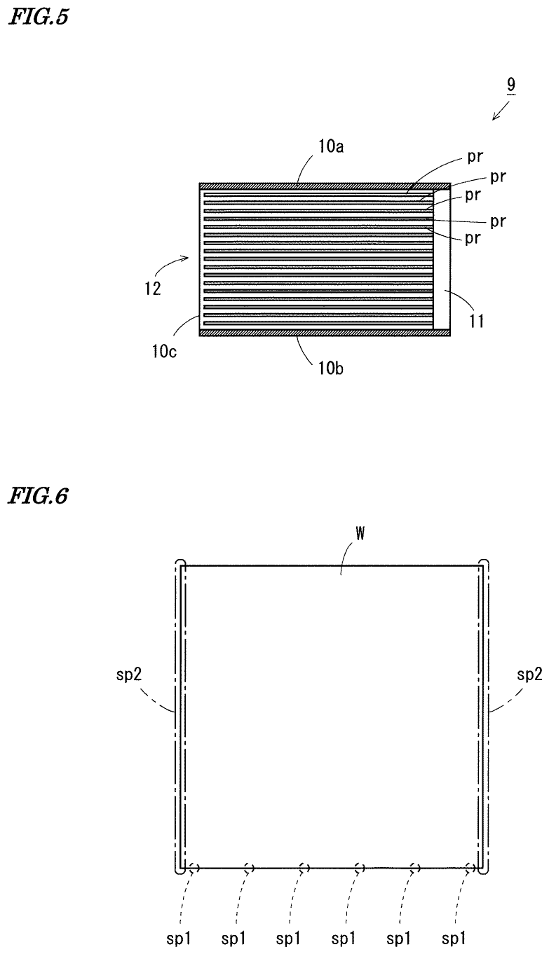

FIG. 6 is a plan view showing a supported portion of the substrate which changes in accordance with the posture of the carrier 9. In a case in which a plurality of substrates W are inserted into the empty carrier 9, the plurality of substrates W are inserted into the carrier 9 from the substrate inlet-outlet port 12 of the carrier 9 having the horizontal posture. At this time, both side portions (portions of two edges opposite to each other) of the outer edge of each substrate W are inserted between any two of the plurality of projections pr of the frame member 10c and any two of the plurality of projections pr of the frame member 10d. Thus, in a case in which the carrier 9 containing the plurality of substrates W has the horizontal posture, each substrate W is held with the both side portions of the substrate supported by the plurality of projections pr. That is, in regard to each of the plurality of substrates W contained in the carrier 9 having the horizontal posture, the both side portions of the substrate W, as a whole, forms supported portions SP2 as indicated by the one-dot and dash lines in FIG. 6.

On the other hand, in a case in which the carrier 9 containing the plurality of substrates W has the vertical posture, each substrate W is held with a plurality of minute portions (six minute portions in the present example) of the lower end portion of the substrate W fitted into the plurality of grooves of the plurality of support pieces 11. That is, in each of the plurality of substrates W contained in the carrier 9 having the vertical posture, the plurality of minute portions that are separated from one another on one edge of the substrate W form supported portions SP1 as indicated by the dotted lines in FIG. 6.

As described above, in a case in which the carrier 9 has the horizontal posture, the both side portions of each of the plurality of contained substrates W, as a whole, are supported by the plurality of projections pr as the supported portions SP2. On the other hand, in a case in which the carrier 9 has the vertical posture, each of the plurality of contained substrates W is supported by the plurality of support pieces 11 with the plurality of minute portions on one side of the lower end portion of the substrate W as the supported portions SP1. As shown in FIG. 6, the total area of the supported portions SP2 of each substrate W obtained when the carrier 9 has the horizontal posture is larger than the total area of the supported portions SP1 of each substrate W obtained when the carrier 9 has the vertical posture. Therefore, in a case in which the carrier 9 has the horizontal posture, a load applied to the supported portions SP2 of each substrate W is reduced as compared with a load applied to the supported portions SP2 of each substrate W when the carrier 9 has the vertical posture (a load that is applied due to the weight of each substrate W).

The carrier 9 according to the present embodiment is formed such that the dimension (height) of the carrier 9 in the vertical direction obtained when the carrier 9 has the horizontal posture is smaller than the dimension (height) of the carrier 9 in the vertical direction obtained when the carrier 9 has in the vertical posture.

### <3> Transport Path for Plurality of Substrates W and Carrier 9 in Substrate Processing Apparatus

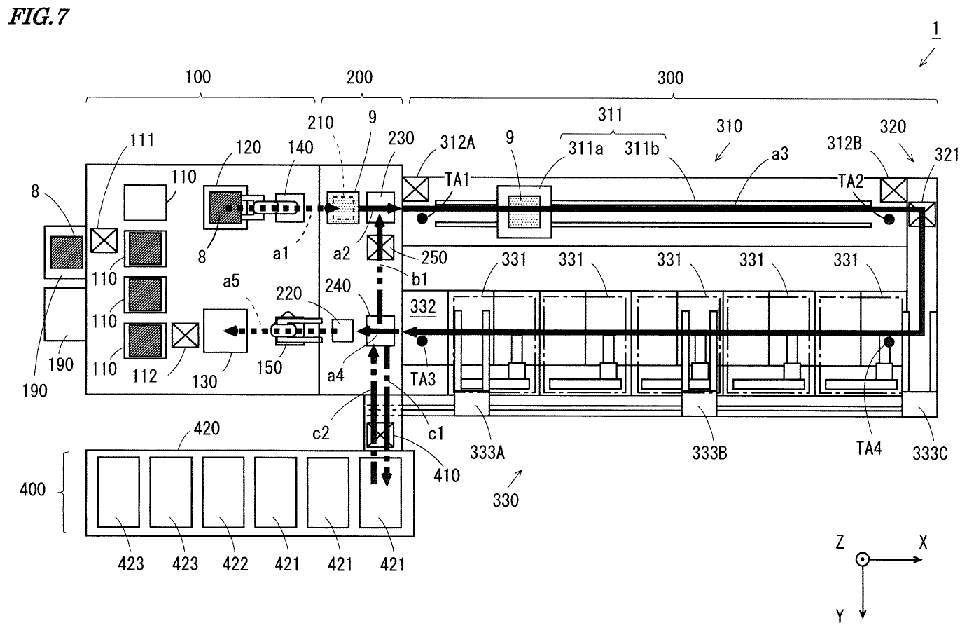

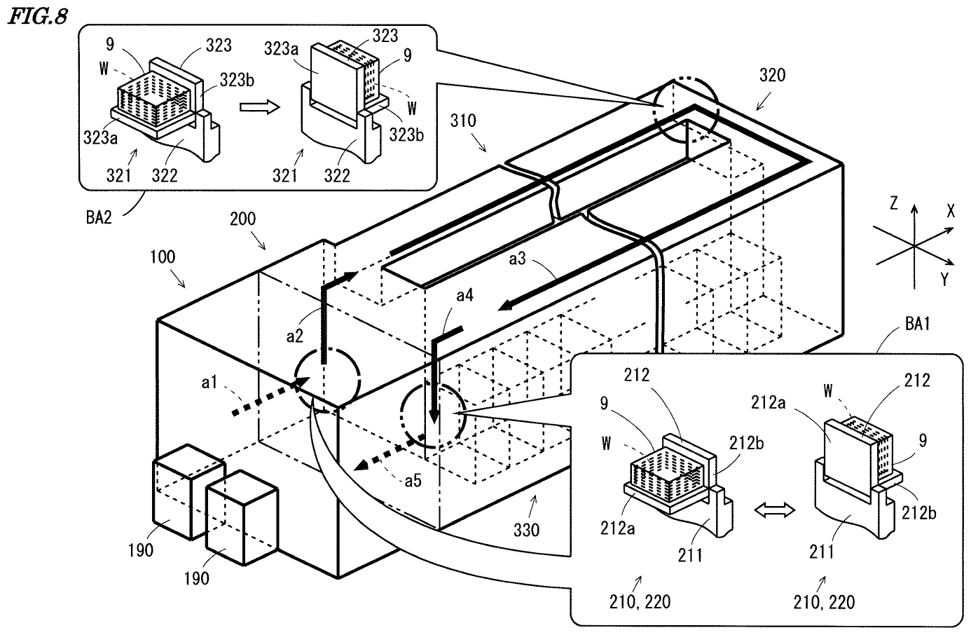

FIGS. 7 to 9 are diagrams for explaining the transport path for the plurality of substrates W and the carrier 9 in the substrate processing apparatus 1 of FIG. 1. FIG. 7 is a schematic plan view of the substrate processing apparatus 1 similarly to FIG. 1. FIG. 8 is a schematic external perspective view of the substrate processing apparatus 1 of FIG. 1 as viewed in one direction. FIG. 9 is a schematic external perspective view of the substrate processing apparatus 1 of FIG. 1 as viewed in another direction. In each of FIGS. 8 and 9, the cleaning block 400 of FIG. 1 is not shown. Further, in each of FIGS. 7 to 9, the maintenance spaces MS1, MS2 of FIG. 1 are not shown either, except for the maintenance space MS1 of FIG. 9.

Suppose that a series of processes is executed on a plurality of unprocessed substrates W contained in one FOUP 8. In this case, the one FOUP 8 is carried into the substrate carry-in carry-out block 100, so that the one FOUP 8 is placed on the opener 120 as shown in FIG. 7, and the lid is opened. Further, an empty carrier 9 is supported on the carrier supporter 210 in the relay block 200 while having the horizontal posture. At this time, the substrate inlet-outlet port 12 (FIG. 5) of the carrier 9 is directed in the −X direction so as to be opposite to the FOUP 8. In this state, the plurality of unprocessed substrates W are taken out from the one FOUP 8 and inserted into the carrier 9 by the substrate receiving-transferring robot 140. The transport path for the plurality of substrates W in this case is indicated by the thick dotted arrow a1 in each of FIGS. 7 to 9.

Thereafter, the lid of the empty FOUP 8 is closed, and the emptied FOUP 8 is held by the FOUP transport device 112 and placed on one of the plurality of FOUP shelves 110. On the other hand, the carrier 9 containing the plurality of substrates W is received by the carrier supporter 210 and placed on the movable stage 311a of the main transport device 311 by the sub-transport device 312A of the first transport section 310. The transport path for the carrier 9 in this case is indicated by the thick solid arrow a2 in each of FIGS. 7 to 9.

Next, the carrier 9 placed on the movable stage 311a is transported while having the horizontal posture in the +X direction from a position in the vicinity of the relay block 200 (the first end portion TA1) to a position in the vicinity of the second transport section 320 (second end portion TA2). In the balloon BA3 of FIG. 9, the state of the carrier 9 transported by the main transport device 311 of the first transport section 310 is shown.

Thereafter, the carrier 9 that has reached the position in the vicinity of the second transport section 320 is transferred to the transport device 321 in the second transport section 320 by the sub-transport device 312B in the first transport section 310. As such, the carrier 9 that has been transferred to the transport device 321 is changed from having the horizontal posture to having the vertical posture by the transport device 321. In the balloon BA2 of FIG. 8, the state of the posture change of the carrier 9 in the transport device 321 is schematically shown.

As shown in the balloon BA2 of FIG. 8, the transport device 321 includes a movable base 322 and a carrier holder 323. The movable base 322 is provided so as to be movable in the Y direction in the second transport section 320. The carrier holder 323 is constituted by a first holder 323a and a second holder 323b. The first holder 323a has a rectangular flat-shape capable of holding the lower end portion of the carriers 9 having the horizontal posture. Further, the second holder 323b has a rectangular flat-shape capable of holding the lower end portion of the carrier 9 having the vertical posture.

The first holder 323a and the second holder 323b are connected to each other such that one edge of the first holder 323a and one edge of the second holder 323b are in contact with each other and the two holders are orthogonal to each other. The movable base 322 holds a portion of the carrier holder 323 such that both of the first holder 323a and the second holder 323b are parallel to the Y direction and the carrier holder 323 is rotatable about an axis extending in the Y direction.

The transport device 321 further has a driver (not shown) capable of adjusting the rotation angle of the carrier holder 323 on the movable base 322. Thus, in a case in which the carrier holder 323 receives the carrier 9 having the horizontal posture from the first transport section 310, the rotation angle of the carrier holder 323 is adjusted such that the first holder 323a is horizontal and the second holder 323b is vertical. Thereafter, when the carrier holder 3232 receives the carrier 9 having the horizontal posture on the carrier holder 323, the rotation angle of the carrier holder 323 is adjusted such that the first holder 323a is vertical and the second holder 323b is horizontal. Thus, the posture of the carrier 9 is changed from the horizontal posture to the vertical posture.

The transport device 321 further has a driver (not shown) that moves the movable base 322 in the Y direction in the second transport section 320. Thus, the carrier 9 keeping the vertical posture is transported while having the vertical posture in the +Y direction from a position in the vicinity of the first transport section 310 to a position in the vicinity of the processing section 330.

Thereafter, the carrier 9 that have reached the position in the vicinity of the processing section 330 is received by the main transport device 333C in the processing section 330 from the transport device 321. The carrier 9 that has been received by the main transport device 333C is transported to one of the one or plurality of liquid processing units 331 by the main transport device 333C and the other main transport devices 333B, 333A, and is immersed in various processing liquids for a predetermined period while keeping the vertical posture. Thus, the plurality of substrates W contained in the carrier 9 are processed in accordance with the processing liquid in which the substrates W are immersed. In the balloon BA4 of FIG. 9, the state of the carrier 9 transported by the main transport devices 333A, 333B, 333C in the processing section 330 is shown.

As shown in the balloon BA4 in FIG. 9, each of the main transport devices 333A, 333B, 333C includes a movable support column 333a and a pair of chuck members 333b. The movable support column 333a is provided sidewardly (in +Y direction) of the plurality of liquid processing units 331 so as to be movable in the X direction and movable in the Z direction (liftable and lowerable). The pair of chuck members 333b is provided so as to extend upwardly of the liquid processing unit 331 from the upper end portion of movable support column 333a. The pair of chuck members 333b is configured to be capable of holding the carrier 9 having the vertical posture therebetween. Further, each of the main transport devices 333A, 333B, 333C includes a driver (not shown) capable of switching between holding the carrier 9 using the pair of chuck members 333b and releasing the carrier 9 from the pair of chuck members 333b. Thus, the carrier 9 is received and transferred between the plurality of main transport devices 333A, 333B, 333C and the plurality of liquid processing units 331.

Thereafter, the carrier 9 containing the plurality of substrates W that have been processed by the processing liquid is further transported to the drying unit 332 in the vicinity of the relay block 200. Thus, the carrier 9 and the plurality of substrates W in the carrier 9 are dried by the drying unit 332. As described above, a series of transport paths for the carrier 9 in the processing block 300 is indicated by thick solid arrow a3 in each of FIGS. 7 to 9.

The carrier 9 containing the plurality of processed substrates W is transported from the drying unit 332 to the carrier supporter 220 in the relay block 200 by the main transport device 333A, and is supported by the carrier supporter 220. The transport path for the carrier 9 in this case is indicated by the thick dotted arrow a4 in each of FIGS. 7 to 9.

As such, the carrier 9 transferred to the carrier supporter 220 is changed from having the vertical posture to having the horizontal posture by the carrier supporter 220. In the balloon BA1 of FIG. 8, the state of the posture change of the carrier 9 in the carrier supporter 220 is schematically shown.

As shown in the balloon BA1 of FIG. 8, the carrier supporter 220 includes a base 211 that is fixed in the relay block 200 and a carrier holder 212. The carrier holder 212 is constituted by a first holder 212a and a second holder 212b. The first holder 212a has a rectangular flat-shape capable of holding the lower end portion of the carrier 9 having the horizontal posture. Further, the second holder 212b has a rectangular flat-shape capable of holding the lower end portion of the carrier 9 having the vertical posture.

The first holder 212a and the second holder 212b are connected to each other such that one edge of the first holder 212a and one edge of the second holder 212b are in contact with each other and the two holders are orthogonal to each other. The fixed base 211 holds a portion of the carrier holder 212 such that both of the first holder 212a and the second holder 212b are parallel to the Y direction and the carrier holder 212 is rotatable about an axis extending in the Y direction.

The carrier supporter 220 further has a driver (not shown) capable of adjusting the rotation angle of the carrier holder 212 on the fixed base 211. Thus, in a case in which the carrier holder 212 receives the carrier 9 having the vertical posture from the drying unit 332, the rotation angle of the carrier holder 212 is adjusted such that the second holder 212b is horizontal and the first holder 212a is vertical. Thereafter, when the carrier holder 212 receives the carrier 9 having the vertical posture on the carrier holder 212, the rotation angle of the carrier holder 212 is adjusted such that the second holder 212b is vertical and the first holder 212a is horizontal. Thus, the posture of the carrier 9 is changed from the vertical posture to the horizontal posture. At this time, the substrate inlet-outlet port 12 (FIG. 5) of the carrier 9 is directed in the −X direction.

When the carrier 9 containing the plurality of substrates W is supported by the carrier supporter 220 while having horizontal posture, an empty FOUP 8 is placed on the opener 130 in the substrate carry-in carry-out block 100. Further, the lid of the FOUP 8 is opened. In this state, the plurality of processed substrates W are taken out by the substrate receiving-transferring robot 150 from the carrier 9 and are inserted into the FOUP 8 on the opener 130. The transport path for the plurality of substrates W in this case is indicated by the thick dotted arrow a5 in each of FIGS. 7 to 9.

Thereafter, the lid of the FOUP 8 containing the plurality of processed substrates W is closed, and the FOUP 8 is held by the FOUP transport device 112 and placed on one of the plurality of FOUP shelves 110. Further, the FOUP 8 is transported to the FOUP platform 190 by the FOUP transport device 111 and is carried out from the substrate processing apparatus 1. On the other hand, the posture of the carrier 9 which has been emptied in the carrier supporter 220 is changed again from the horizontal posture to the vertical posture by the carrier supporter 220. The empty carrier 9 the posture of which has been changed back to the vertical posture in the carrier supporter 220 is transported by the main transport device 333A and received by the second waiting portion 240.

In the present embodiment, the empty carrier 9 that has been received from the carrier supporter 220 by the second waiting portion 240 is transported to the carrier cleaning unit 420 by the cleaning transport device 410 in the cleaning block 400 while keeping the vertical posture. The transport path for the carrier 9 in this case is indicated by the thick one-dot and dash arrow c1 in FIG. 7.

In the carrier cleaning unit 420, the carrier 9 is further transported by the cleaning transport device 410 among the plurality of carrier cleaning tanks 421, the carrier drier 422 and the plurality of carrier waiting portions 423. Thus, the cleaning process and the drying process are executed on the used carrier 9. Further, the carrier 9 after the cleaning process and the drying process is contained in one of the plurality of carrier waiting portions 423. In each of the plurality of carrier cleaning tanks 421, the carrier drier 422 and the plurality of carrier waiting portions 423, the carrier 9 keeps the vertical posture.

Suppose that a series of processes is executed on a plurality of unprocessed substrates W contained in another new FOUP 8. In this case, a clean carrier 9 contained in the carrier waiting portion 423 in the cleaning block 400 is transported as the new carrier 9 from the carrier cleaning unit 420 to the second waiting portion 240 by the cleaning transport device 410. The transport path for the carrier 9 in this case is indicated by the thick one-dot and dash arrow c2 in FIG. 7.

The new carrier 9 transferred to the second waiting portion 240 is transported to the first waiting portion 230 by the waiting transport device 250 while keeping the vertical posture, and is supported by the first waiting portion 230. The transport path for the carrier 9 in this case is indicated by the thick two-dot and dash arrow b1 in FIG. 7. The first waiting portion 230 transfers the new carrier 9 supported by the first waiting portion 230 to the carrier supporter 210. As such, the posture of the carrier 9 that has been transferred to the carrier supporter 210 is changed from the vertical posture to the horizontal posture by the carrier supporter 210. As described above, the two carrier supporters 210, 220 in the relay block 200 have the same configuration. Thus, in the carrier supporter 210, the posture of the new carrier 9 is changed as shown in the balloon BA1 of FIG. 8. Thereafter, a plurality of unprocessed substrates W contained in another new FOUP 8 are inserted into the new carrier 9 having the horizontal posture.

The new carrier 9 containing the plurality of unprocessed substrates W is transported along the transport path indicated by the series of arrows a2, a3 and a4 in FIGS. 7 to 9. Thus, the series of processes is executed on the plurality of substrates W contained in the new carrier 9.

### <4> Effects

(1) In the above-mentioned substrate processing apparatus 1, the carrier 9 is transported from the first end portion TA1 toward the third end portion TA3 on the transport path indicated by the arrow a3 in FIG. 7 by the plurality of transport devices (311, 321, 333A, 333B, 333C). The carrier 9 is configured to be capable of containing the plurality of substrates W. In this case, each of the plurality of transport devices (311, 321, 333A, 333B, 333C) can integrally handle the plurality of substrates W by transporting the carrier 9 containing the plurality of substrates W. Therefore, each of the plurality of transport devices (311, 321, 333A, 333B, 333C) does not require a complicated configuration for integrally and directly holding the plurality of substrates W.

Further, in the above-mentioned substrate processing apparatus 1, the posture of the carrier 9 is changed from the horizontal posture to the vertical posture by the transport device 321 provided on the transport path indicated by the arrow a3 in FIG. 7. Thus, in the processing section 330, the carrier 9 keeps the vertical posture. In this case, in the processing section 330, because the plurality of substrates W contained in the carrier 9 are contained while having the vertical posture, it is possible to appropriately execute a collective process on the plurality of substrates W, such as a process of immersing the plurality of substrates W in a processing liquid.

On the other hand, in the above-mentioned substrate processing apparatus 1, the carrier 9 keeps the horizontal posture in the first transport section 310 located upstream of the processing section 330 in the transport path indicated by the arrow a3 in FIG. 7. When the carrier 9 has the horizontal posture, the plurality of substrates W contained in the carrier 9 keep the horizontal posture.

In regard to each of the plurality of substrates W, the size of the substrate W having a horizontal posture in plan view is larger than the size of the substrate W having a vertical posture in plan view. Therefore, in regard to the substrate W having the horizontal posture, a larger portion of the substrate W can be supported as compared to the substrate W having the vertical posture. Therefore, as described above, the total area of the supported portions SP2 of each substrate W obtained when the carrier 9 has the horizontal posture can be made larger than the total area of the supported portions SP1 of each substrate W obtained when the carrier 9 has the vertical posture. This reduces the possibility that each substrate W is damaged due to the concentration of the weight of the substrate W on one portion of the substrate W when the plurality of substrates W are transported.

As a result of combining the transport of the carrier 9 containing the plurality of substrates W and keeping the vertical posture and the transport of the carrier 9 containing the plurality of substrates W and keeping the horizontal posture, it is possible to suppress complication of the configuration of the plurality of transport devices (311, 321, 333A, 333B, 333C) for transporting the plurality of substrates W and reduce the possibility of damage to the substrates W during the transport of the plurality of substrates W.
(2) In the above-mentioned substrate processing apparatus 1, the first transport section 310 is provided on the transfer path indicated by the arrow a3 in FIG. 7 within a continuous range including the start point of the transport path. On the other hand, the processing section 330 is provided on the transport path indicated by the arrow a3 in FIG. 7 within a continuous range including the end point of the transport path. On the other hand, the second transport section 320 in which the posture of the carrier 9 is changed is located downstream of the first transport section 310 and upstream of the processing section 330 in the transport path indicated by the arrow a3 in FIG. 7.

With such a configuration, in the transport path indicated by the arrow a3 in FIG. 7, the posture of the plurality of substrates W immersed in the processing liquid together with the carrier 9 in the processing section 330 is not changed to the horizontal posture. That is, the plurality of substrates W after being immersed in the processing liquid are not transported while having the horizontal posture. Therefore, it reduces adhesion of falling particles and the like in the substrate processing apparatus 1 to the plurality of substrates W contained in the carrier 9. Further, because the plurality of substrates W after the process using the processing tank are not transported while having the horizontal posture, the processing liquid is prevented from remaining on the upper surface of each of the plurality of substrates W during the transport.
(3) In the first transport section 310, the carrier 9 is transported from the first end portion TA1 to the second end portion TA2 by the main transport device 311. More specifically, the movable stage 311a moves on the guide rail 311b with the carrier 9 placed on the movable stage 311a. Thus, the carrier 9 is transported while having the horizontal posture. In this manner, in the above-mentioned first transport section 310, the carrier 9 can be transported from the first end portion TA1 to the second end portion TA2 without moving in the vertical direction. Therefore, the first transport section 310 can reduce the size in the vertical direction of the space required for transporting the carrier 9.
(4) Further, as described above, the carrier 9 is formed such that the dimension (height) in the vertical direction of the carrier 9 obtained when the carrier 9 has the horizontal posture is smaller than the dimension (height) in the vertical direction of the carrier 9 obtained when the carrier 9 has the vertical posture. In the first transport section 310 out of the transport path indicated by the arrow a3 in FIG. 7, the carrier 9 is transported while having the horizontal posture. On the other hand, in the processing section 330 out of the transport path indicated by the arrow a3 in FIG. 7, the carrier 9 is transported while having the vertical posture. Thus, in the first transport section 310, the size in the vertical direction of the space required for transporting the carrier 9 can be reduced as compared to the processing section 330.

### <5> Other Embodiments

(1) While the carrier 9 according to the above-mentioned embodiment supports the both side portions of the rectangular substrate W, as a whole, using the plurality of projections pr in a case in which the rectangular substrate W is contained while having the horizontal posture, the present invention is not limited to this. The carrier 9 may be configured to support the outer edge of each of the plurality of substrates W, as a whole, while having the horizontal posture. That is, the carrier 9 may be configured to support the four edges of each of the plurality of substrates W and the vicinity thereof, as a whole, while having the horizontal posture. Alternatively, the carrier 9 may be configured to support one portion of each of the both side portions of the substrate W while having the horizontal posture. Specifically, in the carrier 9 of each of FIGS. 3 to 5, each of the plurality of projections pr may be formed so as to extend intermittently in the direction of the long edges of the frame members 10c, 10d. Alternatively, the carrier 9 may be configured to support the center portion or substantially the center portion of the substrate W while having the horizontal posture. Also in these cases, the total area of the supported portions SP2 of each substrate W obtained when the carrier 9 has the horizontal posture is made larger than the total area of the supported portions SP1 of each substrate W obtained when the carrier 9 has the vertical posture. Therefore, the effects similar to those of the above-mentioned embodiment can be obtained.
(2) In the above-mentioned substrate processing apparatus 1, each of the substrate receiving-transferring robots 140, 150 may be configured to be capable of sequentially receiving and transferring the plurality of substrates W one by one, or may be configured to be capable of receiving and transferring the plurality of substrates W at the same time.
(3) In the above-mentioned processing block 300, the carrier 9 transferred from the relay block 200 is transported from the first end portion TA1 to the second end portion TA2 in the first transport section 310. Thereafter, various types of processes are executed on the plurality of substrates W in the period during which the carrier 9 returns to the third end portion TA3 from the fourth end portion TA4 in the processing section 330. However, the present invention is not limited to the above-mentioned example.

The processing block 300 may have a configuration in which the position of the first transport section 310 and the position of the processing section 330 are interchanged. In this case, the processing section 330 has a symmetrical configuration with respect to the plane orthogonal to the X direction, for example. In the processing block 300 having such a configuration, the carrier 9 transferred from the relay block 200 is immersed in the plurality of processing liquids in the processing section 330 while keeping the vertical posture, and is subjected to the drying process. Thereafter, in the second transport section 320, the posture of the carrier 9 is changed from the vertical posture to the horizontal posture. Thereafter, the carrier 9 containing the plurality of processed substrates W is returned to the relay block 200 by the main transport device 311 in the first transport section 310 while keeping the horizontal posture.
(4) In the substrate processing apparatus 1 according to the above-mentioned embodiment, the frame members 10a, 10b of the carrier 9 having the vertical posture are kept parallel to the vertical direction. However, the frame members 10a, 10b of the carrier 9 having the vertical posture may be kept substantially parallel to the vertical direction. That is, the carrier 9 having the vertical posture is simply required to hold the plurality of contained substrates W such that the substrates W are parallel or substantially parallel to the vertical direction.

Further, in the substrate processing apparatus 1 according to the above-mentioned embodiment, the frame members 10a, 10b of the carrier 9 having the horizontal posture are kept orthogonal to the vertical direction. However, the frame members 10a, 10b of the carrier 9 having the horizontal posture may be kept substantially orthogonal to the vertical direction. That is, the carrier 9 having the horizontal posture is simply required to hold the plurality of contained substrates W such that the substrates W are parallel or substantially parallel to the horizontal direction.
(5) While the substrate processing apparatus 1 according to the above-mentioned embodiment includes the cleaning block 400 for cleaning the carrier 9 that has been used in the process for the plurality of substrate W, the present invention is not limited to this. The cleaning block 400 does not have to be provided in the substrate processing apparatus 1. In this case, the used carrier 9 from which the plurality of substrates W have been taken out in the carrier supporter 220 in the relay block 200 may be transported to the carrier supporter 210 without being cleaned. Alternatively, the used carrier 9 may be taken out of the substrate processing apparatus 1 and discarded without being cleaned.
(6) While the carrier supporter 210 and the first waiting portion 230 are separately provided in the relay block 200 in the substrate processing apparatus 1 according to the above-mentioned embodiment, the present invention is not limited to this. In a case in which the function for changing the posture of the carrier 9 can be added to the first waiting portion 230, the carrier supporter 210 does not have to be provided.

While the carrier supporter 220 and the second waiting portion 240 are separately provided in the relay block 200 in the substrate processing apparatus 1 according to the above-mentioned embodiment, the present invention is not limited to this. In a case in which the function for changing the posture of the carrier 9 can be added to the second waiting portion 240, the carrier supporter 220 does not have to be provided.
(7) While the transport device 321 has the function for changing the posture of the carrier 9 and has the function of transporting the carrier 9 in the second transport section 320 of the processing block 300 according to the above-mentioned embodiment, the present invention is not limited to this. In the second transport section 320, a constituent element having the function of changing the posture of the carrier 9 and a constituent element having the function of transporting the carrier 9 may be separately provided instead of the above-mentioned transport device 321.
(8) While having a rectangular shape in plan view in the substrate processing apparatus 1 according to the above-mentioned embodiment, the substrate W to be processed may have a circular shape in plan view or a polygonal shape other than a quadrangular shape, such as a triangular shape or a pentagonal shape in plan view.
(9) While the processing liquid for cleaning the substrate W is stored in each of the plurality of processing tanks 331a in the processing section 330 in the substrate processing apparatus 1 according to the above-mentioned embodiment, the present invention is not limited to this. In at least part of the plurality of processing tanks 331a in the processing section 330, a plating liquid for executing a plating process on the substrates W, liquid for modifying the surface state of the substrates W, or the like may be stored as a processing liquid. In this manner, the above-mentioned embodiment is an example in which the present invention is applied to the cleaning process for the plurality of substrates W. However, the present invention is not limited to this. The present invention may be applied to another process such as a plating process or a surface modification process for the plurality of substrates W.
(10) While the four openings 13 are formed in the center portion of each of the frame members 10a, 10b in the carrier 9 according to the above-mentioned embodiment, the present invention is not limited to this. The number of the openings 13 formed in the center portion of each of the frame members 10a, 10b is not limited to four, and may be one, two, three, five or any other number. Alternatively, the opening 13 does not have to be formed in the center portion of each of the frame members 10a, 10b. Further, the design in regard to the shape of the frame members 10a, 10b may be suitably changed.
(11) While the carrier 9 is held because the pair of chuck members 333b holds the carrier 9 therebetween in the X direction in each of the main transport devices 333A, 333B, 333C according to the above-mentioned embodiment, the present invention is not limited to this. The pair of chuck members 333b may hold the carrier 9 by holding the carrier 9 therebetween in the Y direction, or may hold the carrier 9 by holding the carrier 9 therebetween in the direction intersecting with the X direction and the Y direction in a horizontal plane.

### <6> Correspondences Between Constituent Elements in Claims and Parts in Preferred Embodiments

In the following paragraphs, non-limiting examples of correspondences between various elements recited in the claims below and those described above with respect to various preferred embodiments of the present invention are explained.

In the above-mentioned embodiment, the carrier 9 is an example of a carrier, the transport path for the carrier 9 indicated by the arrow a3 in FIG. 7 is an example of a predetermined transport path, the direction indicated by the arrow a3 in FIG. 7 is an example of one transport direction, and the constituent element group including the main transport devices 311, 333A, 333B, 333C and the transport device 321 in the processing block 300 is an example of a transport mechanism.

Further, the portion of the transport path of the carrier 9 indicated by the arrow a3 in FIG. 7 overlapping with the processing section 330 is an example of a predetermined processing portion, the plurality of liquid processing units 331 in the processing section 330 are an example of processing units, the vertical posture of the carrier 9 is an example of a first posture, the horizontal posture of the carrier 9 is an example of a second posture, and the transport device 321 is an example of a posture changer.

Further, the substrate processing apparatus 1 is an example of a substrate processing apparatus, the processing tank 331a is an example of a processing tank, the lifter 331b is an example of a lifter, the substrate carry-in carry-out block 100 and the relay block 200 are examples of a substrate carry-in carry-out portion, the first end portion TA1 in the first transport section 310 is an example of a start point of a transport path, and the third end portion TA3 in the processing section 330 is an example of an end point of a transport path.

Further, the main transport device 311 is an example of a horizontal transport device, the guide rail 311b is an example of a guide member, the movable stage 311a is an example of a movable stage, the plurality of support pieces 11 of the carrier 9 are an example of a first supporter, and the plurality of projections pr of the carrier 9 is an example of a second supporter.

1. A substrate processing apparatus comprising:
a carrier configured to contain a plurality of substrates;
a transport mechanism that transports the carrier in one predetermined transport direction on a predetermined transport path;
a processing unit that is provided on a predetermined processing portion of the transport path, and executes a predetermined process on the plurality of substrates contained in the carrier, the plurality of substrates being contained in the carrier; and
a posture changer that changes a posture of the carrier between a first posture with which the plurality of substrates are containable while having a vertical posture and a second posture with which the plurality of substrates are containable while having a horizontal posture, wherein
the posture changer is provided on the transport path such that the carrier keeps the first posture in the processing portion of the transport path and the carrier keeps the second posture in at least part of a non-processing portion excluding the processing portion of the transport path with the plurality of substrates contained in the carrier.

2. The substrate processing apparatus according to claim 1, wherein
the processing unit includes
a processing tank that stores a processing liquid corresponding to the predetermined process, and
a lifter configured to immerse the carrier transported by the transport mechanism in a processing liquid of the processing tank and pull up the carried immersed in the processing liquid from the processing liquid, and
because the plurality of substrates are immersed in the processing liquid while being contained in the carrier and having the first posture, the carrier is configured to immerse the plurality of substrates contained in the carrier in the processing liquid.

3. The substrate processing apparatus according to claim 2, further comprising a substrate carry-in carry-out portion that is configured to carry a plurality of unprocessed substrates and insert the plurality of carried substrates into one carrier, and take out a plurality of substrates from another carrier containing the plurality of processed substrates and carry out the plurality of taken substrates, wherein
a start point and an end point of the transport path are set adjacent to the substrate carry-in carry-out portion,
the processing portion of the transport path is defined in a continuous range including the end point of the transport path, and
in the transport path, the posture changer is located at a position farther downstream than at least part of the non-processing portion and farther upstream than the processing portion.

4. The substrate processing apparatus according to claim 1, wherein
at least part of the non-processing portion of the transport path is located in one horizontal plane,
the transport mechanism includes a horizontal transport device provided in at least part of the non-processing portion of the transport path, and
the horizontal transport device includes
a guide member extending horizontally along the transport path, and
a movable stage on which the carrier is placeable and which is movable along the transport path on the guide member.

5. The substrate processing apparatus according to claim 1, wherein
the carrier is formed such that a dimension in a vertical direction of the carrier having the second posture is smaller than a dimension in the vertical direction of the carrier having the first posture.

6. The substrate processing apparatus according to claim 1, wherein
the carrier has
a first supporter that supports a first supported portion of each of the plurality of substrates when the carrier has the first posture, and
a second supporter that supports a second supported portion of each of the plurality of substrates when the carrier has the second posture, and
a size of the second supported portion of the substrate obtained when each of the plurality of substrates having a horizontal posture is seen in plan view is larger than a size of the first supported portion of the substrate obtained when each of the plurality of substrates having a vertical posture is seen in plan view.
